(19) United States
(12) Patent Application Publication
(10) Pub. No.: US 2025/0318417 A1
(43) Pub. Date: Oct. 9, 2025

(54) DEPOSITION MASK, METHOD OF MANUFACTURING THE DEPOSITION MASK, AND METHOD OF MANUFACTURING DISPLAY DEVICE USING THE DEPOSITION MASK

(71) Applicant: Samsung Display Co., LTD., Yongin-si (KR)

(72) Inventors: Young Jin SONG, Yongin-si (KR); Seung Hun KIM, Yongin-si (KR); Byeong Hoon CHO, Yongin-si (KR)

(73) Assignee: Samsung Display Co., LTD., Yongin-si (KR)

(21) Appl. No.: 19/013,411

(22) Filed: Jan. 8, 2025

(30) Foreign Application Priority Data
Apr. 5, 2024 (KR) 10-2024-0046581

(51) Int. Cl. H10K 71/16; C23C 16/04; H01L 21/02

(52) U.S. Cl. CPC H10K 71/166; C23C 16/042; H01L 21/02642

(57) ABSTRACT

A method of manufacturing a deposition mask includes forming a cell opening which exposes a first opening of a first metal layer from a back surface of the first substrate by etching a portion of the first substrate which corresponds to the first opening from the back surface of the first substrate, depositing a second inorganic layer on a front surface of the second substrate comprising a base layer, and forming a mask membrane which comprises the second inorganic layer disposed in the cell opening by removing a protective layer and the base layer.

### CROSS-REFERENCE TO RELATED APPLICATION(S)

This application claims priority to and benefits of Korean Patent Application No. 10-2024-0046581 under 35 U.S.C. § 119, filed on Apr. 5, 2024 in the Korean Intellectual Property Office, the entire contents of which are incorporated herein by reference.

### BACKGROUND

### 1. Technical Field

The disclosure relates to a deposition mask, a method of manufacturing the deposition mask, and a method of manufacturing a display device using the deposition mask.

### 2. Description of the Related Art

A wearable device that forms a focus at a short distance from a user's eyes is being developed in the form of glasses or a helmet. For example, the wearable device may be a head mounted display (HMD) device or augmented reality (AR) glasses. Such a wearable device provides an AR screen or a virtual reality (VR) screen to a user.

A wearable device such as an HMD device or AR glasses is required to have a display specification of about 3000 pixels per inch (PPI) or higher so that a user can use it for a long time without dizziness. To this end, organic light emitting diode on silicon (OLEDoS) technology, which is a small high-resolution organic light emitting display device, is being proposed. OLEDOS is a technology that places an organic light emitting diode (OLED) on a semiconductor wafer substrate on which a complementary metal oxide semiconductor (CMOS) is disposed.

In order to manufacture a display panel with a high resolution of about 3000 PPI or higher, a high-resolution deposition mask is required. As a deposition mask for manufacturing OLEDOS display panels, a mask in which an inorganic layer is deposited on a silicon substrate and patterned to form a mask membrane is being researched. However, the mask has a high risk of breakage due to a thin thickness of the mask membrane formed of the inorganic layer.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Aspects of the disclosure provide a deposition mask whose rigidity is increased to reduce damage, a method of manufacturing the deposition mask, and a method of manufacturing a display device using the deposition mask.

According to an embodiment of the disclosure, a method of manufacturing a deposition mask may include depositing a first metal layer on a front surface of a first substrate and forming a first opening of the first metal layer and a first bonding portion of the first metal layer by patterning the deposited first metal layer, forming a cell opening which exposes the first opening from a back surface of the first substrate by etching a portion of the first substrate which corresponds to the first opening from the back surface of the first substrate, depositing a first inorganic layer on a front surface of a second substrate and forming a base layer by patterning the deposited first inorganic layer, depositing a second inorganic layer on the front surface of the second substrate comprising the base layer, depositing a second metal layer on the second inorganic layer and forming a second opening of the second metal layer and a second bonding portion of the second metal layer by patterning the deposited second metal layer, depositing an insulating layer on the front surface of the second substrate which comprises the second bonding portion and the second inorganic layer and forming a protective layer which covers the second inorganic layer in the second opening by patterning the deposited insulating layer, forming a plurality of grooves which penetrate the protective layer and the second inorganic layer in the second opening, placing the front surface of the first substrate and the front surface of the second substrate to face each other and bonding the first bonding portion and the second bonding portion to each other, removing the second substrate, and forming a mask membrane which comprises the second inorganic layer disposed in the cell opening by removing the protective layer and the base layer.

In an embodiment, the first substrate may include silicon (Si).

In an embodiment, the second substrate may include sapphire.

In an embodiment, the first inorganic layer may include zinc oxide (ZnO).

In an embodiment, the second inorganic layer may include gallium nitride (GaN).

In an embodiment, the forming of the plurality of grooves may include forming a photoresist pattern, which comprises the plurality of grooves corresponding to the second opening, on the front surface of the second substrate comprising the second bonding portion and the protective layer; and etching the protective layer and the second inorganic layer using the photoresist pattern.

In an embodiment, the method may further include forming a coating layer which covers an entire surface of the first substrate and an entire surface of the mask membrane using atomic layer deposition.

According to an embodiment of the disclosure, a deposition mask may include a first substrate comprising a plurality of cell areas and a mask frame area excluding the plurality of cell areas, a mask membrane disposed in the plurality of cell areas, and a mask frame disposed in the mask frame area and comprising a bonding portion in which a first metal layer and a second metal layer are bonded to each other. The mask membrane may include a second inorganic layer remaining after a second substrate, a first inorganic layer and an insulating layer among the first inorganic layer, the second inorganic layer and the insulating layer sequentially deposited on the second substrate are removed.

In an embodiment, the first substrate may include silicon (Si).

In an embodiment, the second substrate may include sapphire.

In an embodiment, the first inorganic layer may include zinc oxide (ZnO).

In an embodiment, the second inorganic layer may include gallium nitride (GaN).

In an embodiment, deposition mask may further include a coating layer covering an entire surface of the first substrate and an entire surface of the mask membrane.

According to an embodiment of the disclosure, a method of manufacturing a display device may include manufacturing a mask, placing a deposition substrate on a surface of the manufactured mask, placing a deposition source to face a surface of the deposition substrate, and vaporizing a deposition material contained in the deposition source and letting the vaporized deposition material pass through the mask and be deposited on the deposition substrate. The manufacturing of the mask may include depositing a first metal layer on a front surface of a first substrate and forming a first opening of the first metal layer and a first bonding portion of the first metal layer by patterning the deposited first metal layer, forming a cell opening which exposes the first opening from a back surface of the first substrate by etching a portion of the first substrate which corresponds to the first opening from the back surface of the first substrate, depositing a first inorganic layer on a front surface of a second substrate and forming a base layer by patterning the deposited first inorganic layer, depositing a second inorganic layer on the front surface of the second substrate comprising the base layer, depositing a second metal layer on the second inorganic layer and forming a second opening of the second metal layer and a second bonding portion of the second metal layer by patterning the deposited second metal layer, depositing an insulating layer on the front surface of the second substrate which comprises the second bonding portion and the second inorganic layer and forming a protective layer which covers the second inorganic layer in the second opening by patterning the deposited insulating layer, forming a plurality of grooves which penetrate the protective layer and the second inorganic layer in the second opening, placing the front surface of the first substrate and the front surface of the second substrate to face each other and bonding the first bonding portion and the second bonding portion to each other, removing the second substrate, and forming a mask membrane which comprises the second inorganic layer disposed in the cell opening by removing the protective layer and the base layer.

In an embodiment, the first substrate may include silicon (Si).

In an embodiment, the second substrate may include sapphire.

In an embodiment, the first inorganic layer may include zinc oxide (ZnO).

In an embodiment, the second inorganic layer may include gallium nitride (GaN).

In an embodiment, the forming of the plurality of grooves may include forming a photoresist pattern, which comprises the plurality of grooves corresponding to the second opening, on the front surface of the second substrate comprising the second bonding portion and the protective layer; and etching the protective layer and the second inorganic layer using the photoresist pattern.

In an embodiment, the method may further include forming a coating layer which covers an entire surface of the first substrate and an entire surface of the mask membrane using atomic layer deposition.

However, aspects of the disclosure are not restricted to those set forth herein. The above and other aspects of the disclosure will become more apparent to one of ordinary skill in the art to which the disclosure pertains by referencing the detailed description given herein.

### BRIEF DESCRIPTION OF THE DRAWINGS

These and/or other aspects will become apparent and more readily appreciated from the following description of the embodiments, taken in conjunction with the accompanying drawings in which:

FIG. 1 is an exploded schematic perspective view of a display device according to an embodiment;

FIG. 2 is a schematic block diagram of the display device according to an embodiment;

FIG. 3 is a schematic diagram of an equivalent circuit of a first subpixel according to an embodiment;

FIG. 4 is a schematic layout view of an example of a display panel according to an embodiment;

FIGS. 5 and 6 are schematic layout views of embodiments of a display area of FIG. 4;

FIG. 7 is a schematic cross-sectional view of an example of the display panel, taken along line I1-I1′ of FIG. 5;

FIG. 8 is a schematic perspective view of a head mounted display device according to an embodiment;

FIG. 9 is an exploded schematic perspective view of an example of the head mounted display device of FIG. 8;

FIG. 10 is a schematic perspective view of a head mounted display device according to an embodiment;

FIG. 11 is a schematic perspective view of a mask according to an embodiment;

FIG. 12 is a schematic plan view of the mask according to an embodiment;

FIGS. 13 through 24 are schematic cross-sectional views illustrating a method of manufacturing a mask according to an embodiment;

FIG. 25 is a schematic cross-sectional view of a mask for explaining a process of depositing a protective layer on the mask according to an embodiment; and

FIG. 26 schematically illustrates the configuration of deposition equipment according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will also be understood that when a layer is referred to as being “on” another layer or substrate, it can be directly on the other layer or substrate, or intervening layers may also be present. The same reference numbers indicate the same components throughout the specification. In the attached figures, the thickness of layers and regions may be exaggerated for clarity.

Although the terms “first”, “second”, etc. may be used herein to describe various elements, these elements, should not be limited by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Features of various embodiments of the disclosure may be combined partially or totally. As will be clearly appreciated by those skilled in the art, technically various interactions and operations are possible. Various embodiments can be practiced individually or in combination.

“About” or “approximately” or “substantially” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Unless otherwise defined, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

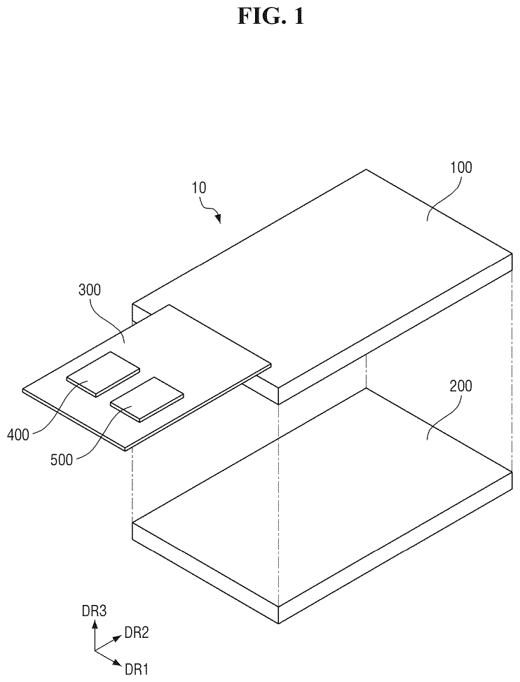

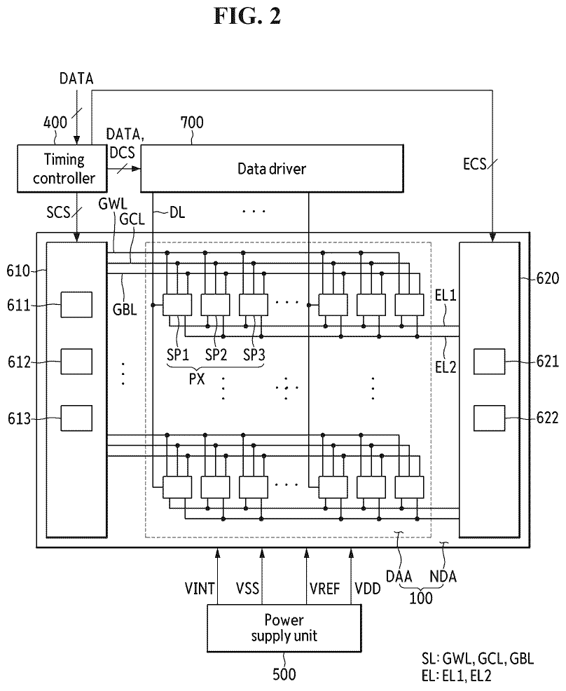

FIG. 1 is an exploded schematic perspective view of a display device 10 according to an embodiment. FIG. 2 is a schematic block diagram of the display device 10 according to an embodiment.

Referring to FIGS. 1 and 2, the display device 10 according to an embodiment may be a device for displaying moving images or still images. The display device 10 according to an embodiment may be applied to portable electronic devices such as mobile phones, smartphones, tablet personal computers (PCs), mobile communication terminals, electronic notebooks, electronic books, portable multimedia players (PMPs), navigation devices, and ultra-mobile PCs (UMPCs). For example, the display device 10 according to an embodiment may be applied as a display unit of a television, a notebook computer, a monitor, a billboard, or an Internet of things (IoT) device. In other embodiments, the display device 10 may be applied to smart watches, watch phones, and head mounted displays for implementing virtual reality and augmented reality.

The display device 10 according to an embodiment may include a display panel 100, a heat dissipation layer 200, a circuit board 300, a timing controller 400, and a power supply unit 500.

The display panel 100 may have a planar shape similar to a quadrangle. For example, the display panel 100 may have a planar shape similar to a quadrangle having short sides in a first direction DR1 and long sides in a second direction DR2 intersecting the first direction DR1. In the display panel 100, each corner where a short side extending in the first direction DR1 meets a long side extending in the second direction DR2 may be rounded with a predetermined curvature or may be right-angled. The planar shape of the display panel 100 is not limited to a quadrangular shape and may also be similar to other polygonal shapes, a circular shape, or an oval shape. The planar shape of the display device 10 may follow the planar shape of the display panel 100, but embodiments of the specification are not limited thereto.

As illustrated in FIG. 2, the display panel 100 may include a display area DAA that displays an image and a non-display area NDA that does not display an image.

The display area DAA may include pixels PX, scan lines SL, emission control lines EL, and data lines DL.

The pixels PX may be arranged in a matrix form in the first direction DR1 and the second direction DR2. The scan lines SL and the emission control lines EL may extend in the first direction DR1 and may be arranged in the second direction DR2. The data lines DL may extend in the second direction DR2 and may be arranged in the first direction DR1.

The scan lines SL may include write scan lines GWL, control scan lines GCL, and bias scan lines GBL. The emission control lines EL include first emission control lines EL1 and second emission control lines EL2.

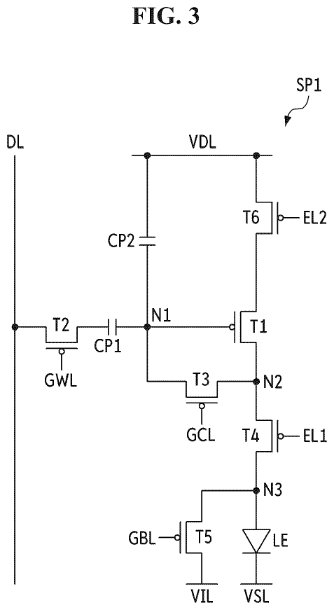

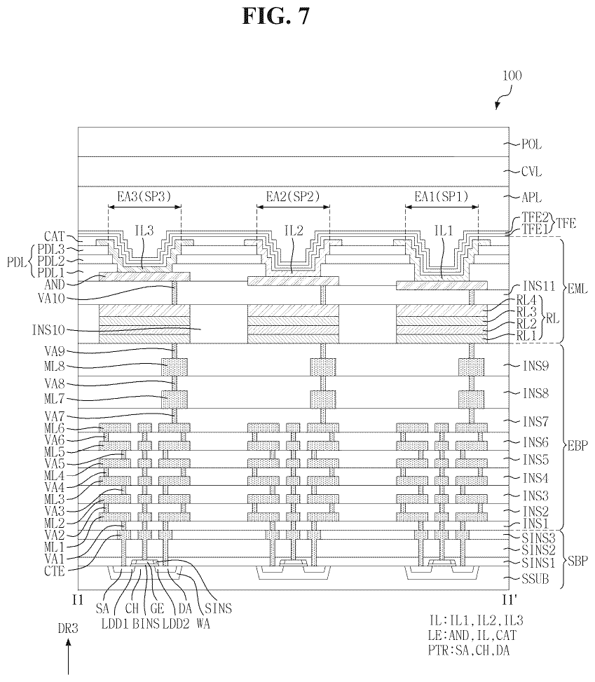

Each of the pixels PX may include subpixels SP1 through SP3. Each of the subpixels SP1 through SP3 may include pixel transistors as illustrated in FIG. 3. The pixel transistors may be formed through a semiconductor process and may be disposed on a semiconductor substrate SSUB (see FIG. 7). For example, pixel transistors of a data driver 700 may be formed as complementary metal oxide semiconductor (CMOS) transistors.

Each of the subpixels SP1 through SP3 may be connected to any one of the write scan lines GWL, any one of the control scan lines GCL, any one of the bias scan lines GBL, any one of the first emission control lines EL1, any one of the second emission control lines EL2, and any one of the data lines DL. Each of the subpixels SP1 through SP3 may receive a data voltage of a data line DL according to a write scan signal of a write scan line GWL and emit light from a light emitting element according to the data voltage.

The non-display area NDA may include a scan driver 610, an emission driver 620, and the data driver 700.

The scan driver 610 may include scan transistors, and the emission driver 620 may include emission transistors. The scan transistors and the emission transistors may be formed through a semiconductor process and may be formed on the semiconductor substrate SSUB (see FIG. 7). For example, the scan transistors and the emission transistors may be formed as CMOS transistors. In FIG. 2, the scan driver 610 is disposed on a left side of the display area DAA, and the emission driver 620 is disposed on a right side of the display area DAA. However, embodiments of the specification are not limited thereto. For example, the scan driver 610 and the emission driver 620 may also be disposed on both the left and right sides of the display area DAA.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing controller 400. The write scan signal output unit 611 may generate write scan signals according to the scan timing control signal SCS of the timing controller 400 and sequentially output the write scan signals to the write scan lines GWL. The control scan signal output unit 612 may generate control scan signals according to the scan timing control signal SCS and sequentially output the control scan signals to the control scan lines GCL. The bias scan signal output unit 613 may generate bias scan signals according to the scan timing control signal SCS and sequentially output the bias scan signals to the bias scan lines GBL.

The emission driver 620 may include a first emission control driving unit 621 and a second emission control driving unit 622. Each of the first emission control driving unit 621 and the second emission control driving unit 622 may receive an emission timing control signal ECS from the timing controller 400. The first emission control driving unit 621 may generate first emission control signals according to the emission timing control signal ECS and sequentially output the first emission control signals to the first emission control lines EL1. The second emission control driving unit 622 may generate second emission control signals according to the emission timing control signal ECS and sequentially output the second emission control signals to the second emission control lines EL2.

The data driver 700 may include data transistors. The data transistors may be formed through a semiconductor process and may be formed on the semiconductor substrate SSUB (see FIG. 7). For example, the data transistors may be formed as CMOS transistors.

The data driver 700 may receive digital video data DATA and a data timing control signal DCS from the timing controller 400. The data driver 700 may convert the digital video data DATA into analog data voltages according to the data timing control signal DCS and may output the analog data voltages to the data lines DL. In this case, subpixels SP1 through SP3 may be selected by a write scan signal of the scan driver 610, and the data voltages may be supplied to the selected subpixels SP1 through SP3.

The heat dissipation layer 200 may overlap the display panel 100 in a third direction DR3 which is a thickness direction of the display panel 100. The heat dissipation layer 200 may be disposed on a surface, e.g., a back surface of the display panel 100. The heat dissipation layer 200 may dissipate heat generated from the display panel 100. The heat dissipation layer 200 may include a metal layer having high thermal conductivity, such as graphite, silver (Ag), copper (Cu), or aluminum (Al).

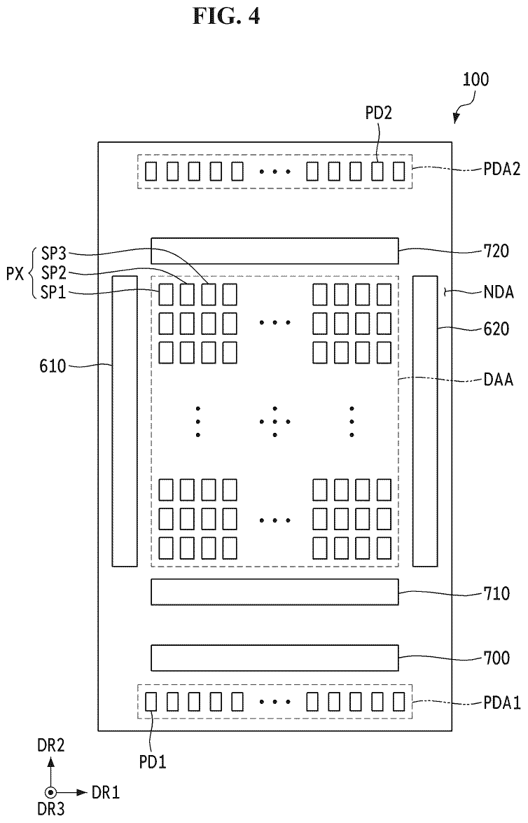

The circuit board 300 may be electrically connected to first pads PD1 (see FIG. 4) in a first pad portion PDA1 (see FIG. 4) of the display panel 100 by using a conductive adhesive member such as an anisotropic conductive film. The circuit board 300 may be a flexible printed circuit board made of a flexible material or may be a flexible film. Although the circuit board 300 is unfolded in FIG. 1, it may also be bent. In this case, an end of the circuit board 300 may be placed on the back surface of the display panel 100 and/or a back surface of the heat dissipation layer 200. The end of the circuit board 300 may be an end opposite another end of the circuit board 300 which is connected to the first pads PD1 (see FIG. 4) in the first pad portion PDA1 (see FIG. 4) of the display panel 100 by using the conductive adhesive member.

The timing controller 400 may receive the digital video data DATA and timing signals from an external source. The timing controller 400 may generate the scan timing control signal SCS, the emission timing control signal ECS, and the data timing control signal DCS for controlling the display panel 100 according to the timing signals. The timing controller 400 may output the scan timing control signal SCS to the scan driver 610 and the emission timing control signal ECS to the emission driver 620. The timing controller 400 may output the digital video data DATA and the data timing control signal DCS to the data driver 700.

The power supply unit 500 may generate panel driving voltages according to a power supply voltage received from an external source. For example, the power supply unit 500 may generate a first driving voltage VSS, a second driving voltage VDD and a third driving voltage VINT and supply them to the display panel 100. In an embodiment, the power supply unit 500 may generate a reference voltage VREF and supply it to the display panel 100. The first driving voltage VSS, the second driving voltage VDD, and the third driving voltage VINT will be described later with reference to FIG. 3.

Each of the timing controller 400 and the power supply unit 500 may be formed as an integrated circuit and attached to a surface of the circuit board 300. In this case, the scan timing control signal SCS, the emission timing control signal ECS, the digital video data DATA, and the data timing control signal DCS of the timing controller 400 may be supplied to the display panel 100 through the circuit board 300. In addition, the first driving voltage VSS, the second driving voltage VDD, and the third driving voltage VINT of the power supply unit 500 may be supplied to the display panel 100 through the circuit board 300.

In other embodiments, each of the timing controller 400 and the power supply unit 500 may be disposed in the non-display area NDA of the display panel 100, like the scan driver 610, the emission driver 620, and the data driver 700. In this case, the timing controller 400 may include timing transistors, and the power supply unit 500 may include power transistors. The timing transistors and the power transistors may be formed through a semiconductor process and may be formed on the semiconductor substrate SSUB (see FIG. 7). For example, the timing transistors and the power transistors may be formed as CMOS transistors. Each of the timing controller 400 and the power supply unit 500 may be disposed between the data driver 700 and the first pad portion PDA1 (see FIG. 4).

FIG. 3 is a schematic diagram of an equivalent circuit of a first subpixel SP1 according to an embodiment.

Referring to FIG. 3, the first subpixel SP1 may be connected to a write scan line GWL, a control scan line GCL, a bias scan line GBL, a first emission control line EL1, a second emission control line EL2, and a data line DL. In addition, the first subpixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. For example, the first driving voltage line VSL may be a low-potential voltage line, the second driving voltage line VDL may be a high-potential voltage line, and the third driving voltage line VIL may be an initialization voltage line. Here, the first driving voltage VSS may be lower than the third driving voltage VINT. The second driving voltage VDD may be higher than the third driving voltage VINT.

The first subpixel SP1 includes transistors T1 through T6, a light emitting element LE, a first capacitor CP1, and a second capacitor CP2.

The light emitting element LE may emit light according to a driving current flowing through a channel of a first transistor T1. The amount of light emitted from the light emitting element LE may be proportional to the driving current. The light emitting element LE may be disposed between a fourth transistor T4 and the first driving voltage line VSL. A first electrode of the light emitting element LE may be connected to a drain electrode of the fourth transistor T4, and a second electrode of the light emitting element LE may be connected to the first driving voltage line VSL. The first electrode of the light emitting element LE may be an anode, and the second electrode of the light emitting element LE may be a cathode. The light emitting element LE may be an organic light emitting diode including a first electrode, a second electrode, and an organic light emitting layer disposed between the first electrode and the second electrode. However, embodiments of the specification are not limited thereto. For example, the light emitting element LE may be an inorganic light emitting element including a first electrode, a second electrode, and an inorganic semiconductor disposed between the first electrode and the second electrode. In this case, the light emitting element LE may be a micro light emitting diode.

The first transistor T1 may be a driving transistor that controls a source-drain current (hereinafter, referred to as a “driving current”) flowing between a source electrode and a drain electrode according to a voltage applied to a gate electrode. The first transistor T1 may include the gate electrode connected to a first node N1, the source electrode connected to a drain electrode of a sixth transistor T6, and the drain electrode connected to a second node N2.

A second transistor T2 may be disposed between an electrode of the first capacitor CP1 and the data line DL. The second transistor T2 may be turned on by a write scan signal of the write scan line GWL and may connect the electrode of the first capacitor CP1 to the data line DL. Accordingly, a data voltage of the data line DL may be applied to the electrode of the first capacitor CP1. The second transistor T2 may include a gate electrode connected to the write scan line GWL, a source electrode connected to the data line DL, and a drain electrode connected to the electrode of the first capacitor CP1.

A third transistor T3 may be disposed between the first node N1 and the second node N2. The third transistor T3 may be turned on by a write control signal of the write control line GCL and may connect the first node N1 to the second node N2. Accordingly, since the gate electrode and source electrode of the first transistor T1 are connected, the first transistor T1 may operate as a diode. The third transistor T3 may include a gate electrode connected to the write control line GCL, a source electrode connected to the second node N2, and a drain electrode connected to the first node N1.

The fourth transistor T4 may be connected between the second node N2 and a third node N3. The fourth transistor T4 may be turned on by a first emission control signal of the first emission control line EL1 and may connect the second node N2 to the third node N3. Accordingly, the driving current of the first transistor T1 may be supplied to the light emitting element LE. The fourth transistor T4 may include a gate electrode connected to the first emission control line EL1, a source electrode connected to the second node N2, and the drain electrode connected to the third node N3.

A fifth transistor T5 may be disposed between the third node N3 and the third driving voltage line VIL. The fifth transistor T5 may be turned on by a bias scan signal of the bias scan line GBL and may connect the third node N3 to the third driving voltage line VIL. Accordingly, the third driving voltage VINT of the third driving voltage line VIL may be applied to the first electrode of the light emitting element LE. The fifth transistor T5 may include a gate electrode connected to the bias scan line GBL, a source electrode connected to the third node N3, and a drain electrode connected to the third driving voltage line VIL.

The sixth transistor T6 may be disposed between the source electrode of the first transistor T1 and the second driving voltage line VDL. The sixth transistor T6 may be turned on by a second emission control signal of the second emission control line EL2 and may connect the source electrode of the first transistor T1 to the second driving voltage line VDL. Accordingly, the second driving voltage VDD of the second driving voltage line VDL may be applied to the source electrode of the first transistor T1. The sixth transistor T6 may include a gate electrode connected to the second emission control line EL2, a source electrode connected to the second driving voltage line VDL, and the drain electrode connected to the source electrode of the first transistor T1.

The first capacitor CP1 may be formed between the first node N1 and the drain electrode of the second transistor T2. The first capacitor CP1 may include an electrode connected to the drain electrode of the second transistor T2 and another electrode connected to the first node N1.

The second capacitor CP2 may be formed between the gate electrode of the first transistor T1 and the second driving voltage line VDL. The second capacitor CP2 may include an electrode connected to the gate electrode of the first transistor T1 and another electrode connected to the second driving voltage line VDL.

The first node N1 may be a contact point between the gate electrode of the first transistor T1, the drain electrode of the third transistor T3, the another electrode of the first capacitor CP1, and the electrode of the second capacitor CP2. The second node N2 may be a contact point between the drain electrode of the first transistor T1, the source electrode of the third transistor T3, and the source electrode of the fourth transistor T4. The third node N3 may be a contact point between the drain electrode of the fourth transistor T4, the source electrode of the fifth transistor T5, and the first electrode of the light emitting element LE.

Each of the first through sixth transistors T1 through T6 may be a metal-oxide-semiconductor field effect transistor (MOSFET). For example, each of the first through sixth transistors T1 through T6 may be a P-type MOSFET. However, embodiments of the specification are not limited thereto. Each of the first through sixth transistors T1 through T6 may also be an N-type MOSFET. In other embodiments, some of the first through sixth transistors T1 through T6 may be P-type MOSFETs, and other transistors may be N-type MOSFETs.

In FIG. 3, the first subpixel SP1 includes six transistors T1 through T6 and two capacitors CP1 and CP2. However, it should be noted that the equivalent circuit diagram of the first subpixel SP1 is not limited to that illustrated in FIG. 3. For example, the number of transistors and the number of capacitors of the first subpixel SP1 are not limited to those illustrated in FIG. 3.

In addition, an equivalent circuit diagram of a second subpixel SP2 and an equivalent circuit diagram of a third subpixel SP3 may be substantially the same as the equivalent circuit diagram of the first subpixel SP1 described with reference to FIG. 3. Therefore, the equivalent circuit diagram of the second subpixel SP2 and the equivalent circuit diagram of the third subpixel SP3 will not be described in the specification.

FIG. 4 is a schematic layout view of an example of a display panel 100 according to an embodiment.

Referring to FIG. 4, a display area DAA of the display panel 100 according to an embodiment may include pixels PX arranged in a matrix form. A non-display area NDA of the display panel 100 according to an embodiment may include a scan driver 610, an emission driver 620, a data driver 700, a first distribution circuit 710, a second distribution circuit 720, a first pad portion PDA1, and a second pad portion PDA2.

The scan driver 610 may be disposed on a first side of the display area DAA, and the emission driver 620 may be disposed on a second side of the display area DAA. For example, the scan driver 610 may be disposed on a side of the display area DAA in the first direction DR1, and the emission driver 620 may be disposed on another side of the display area DAA in the first direction DR1. For example, the scan driver 610 may be disposed on a left side of the display area DAA, and the emission driver 620 may be disposed on a right side of the display area DAA. However, embodiments of the specification are not limited thereto, and the scan driver 610 and the emission driver 620 may also be disposed on both the first and second sides of the display area DAA.

The first pad portion PDA1 may include first pads PD1 connected to pads or bumps of the circuit board 300 through a conductive adhesive member. The first pad portion PDA1 may be disposed on a third side of the display area DAA. For example, the first pad portion PDA1 may be disposed on a side of the display area DAA in the second direction DR2. For example, the first pad portion PDA1 may be disposed on a lower side of the display area DAA.

The first pad portion PDA1 may be disposed outside the data driver 700 in the second direction DR2. For example, the first pad portion PDA1 may be disposed closer to an edge of the display panel 100 than the data driver 700.

The second pad portion PDA2 may include second pads PD2 corresponding to test pads for testing whether the display panel 100 operates normally. The second pads PD2 may be connected to a jig or a probe pin during a test process or may be connected to a test circuit board. The test circuit board may be a printed circuit board made of a rigid material or a flexible printed circuit board made of a flexible material.

The first distribution circuit 710 may distribute data voltages received through the first pad portion PDA1 to data lines DL. For example, the first distribution circuit 710 may distribute data voltages received through a first pad PD1 of the first pad portion PDA1 to P (P is a positive integer of 2 or more) data lines DL. Therefore, the number of first pads PD1 can be reduced. The first distribution circuit 710 may be disposed on the third side of the display area DAA of the display panel 100. For example, the first distribution circuit 710 may be disposed on a side of the display area DAA in the second direction DR2. For example, the first distribution circuit 710 may be disposed on the lower side of the display area DAA.

The second distribution circuit 720 may distribute signals received through the second pad portion PDA2 to the scan driver 610, the emission driver 620, and the data lines DL. The second pad portion PDA2 and the second distribution circuit 720 may be elements for testing the operation of each of the pixels PX in the display area DAA. The second distribution circuit 720 may be disposed on a fourth side of the display area DAA of the display panel 100. For example, the second distribution circuit 720 may be disposed on the another side of the display area DAA in the second direction DR2. That is, the second distribution circuit 720 may be disposed on an upper side of the display area DAA.

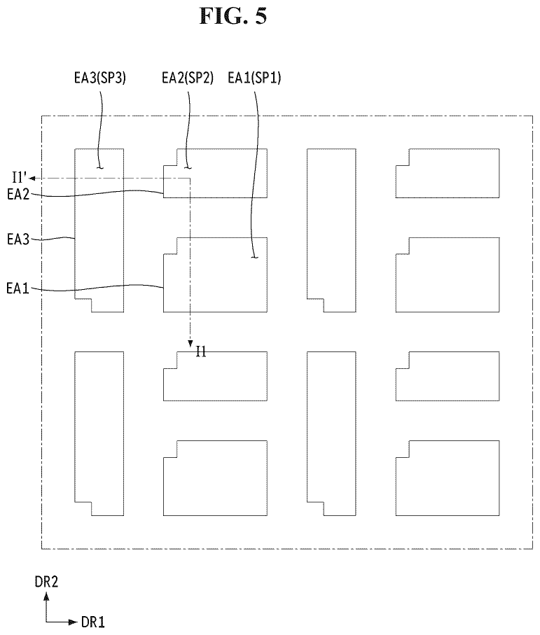

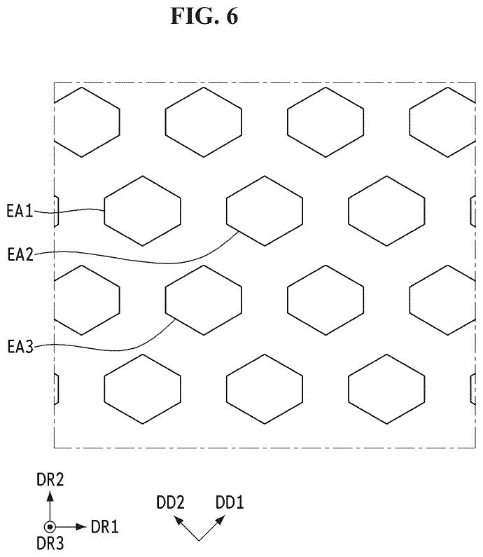

FIGS. 5 and 6 are schematic layout views of embodiments of the display area DAA of FIG. 4.

Referring to FIGS. 5 and 6, each of multiple pixels PX may include a first emission area EA1 which is an emission area of a first subpixel SP1, a second emission area EA2 which is an emission area of a second subpixel SP2, and a third emission area EA3 which is an emission area of a third subpixel SP3.

Each of the first emission area EA1, the second emission area EA2, and the third emission area EA3 may have a polygonal, circular, oval, or irregular planar shape.

A maximum length of the third emission area EA3 in the first direction DR1 may be smaller than a maximum length of the first emission area EA1 in the first direction DR1 and a maximum length of the second emission area EA2 in the first direction DR1. The maximum length of the first emission area EA1 in the first direction DR1 may be substantially the same as the maximum length of the second emission area EA2 in the first direction DR1.

A maximum length of the third emission area EA3 in the second direction DR2 may be greater than a maximum length of the first emission area EA1 in the second direction DR2 and a maximum length of the second emission area EA2 in the second direction DR2. The maximum length of the first emission area EA1 in the second direction DR2 may be greater than the maximum length of the second emission area EA2 in the second direction DR2.

The first emission area EA1, the second emission area EA2, and the third emission area EA3 may have a hexagonal planar shape composed of six straight lines as illustrated in FIGS. 5 and 6. However, embodiments of the specification are not limited thereto. The first emission area EA1, the second emission area EA2, and the third emission area EA3 may also have a polygonal planar shape other than a hexagonal shape or may have a circular, oval or irregular planar shape.

As illustrated in FIG. 5, in each of the pixels PX, the first emission area EA1 and the second emission area EA2 may neighbor each other in the second direction DR2. In addition, the first emission area EA1 and the third emission area EA3 may neighbor each other in the first direction DR1. In addition, the second emission area EA2 and the third emission area EA3 may neighbor each other in the first direction DR1. The area of the first emission area EA1, the area of the second emission area EA2, and the area of the third emission area EA3 may be different.

In other embodiments, as illustrated in FIG. 6, the first emission area EA1 and the second emission area EA2 may neighbor each other in the first direction DR1. However, the second emission area EA2 and the third emission area EA3 may neighbor each other in a first diagonal direction DD1, and the first emission area EA1 and the third emission area EA3 may neighbor each other in a second diagonal direction DD2. The first diagonal direction DD1 may be a direction between the first direction DR1 and the second direction DR2 and a direction inclined by about 45 degrees with respect to the first direction DR1 and the second direction DR2. The second diagonal direction DD2 may be a direction orthogonal to the first diagonal direction DD1.

The first emission area EA1 may emit light of a first color, the second emission area EA2 may emit light of a second color, and the third emission area EA3 may emit light of a third color. Here, the light of the first color may be light in a blue wavelength band, the light of the second color may be light in a green wavelength band, and the light of the third color may be light in a red wavelength band. For example, the blue wavelength band may indicate that a main peak wavelength of light is included in a wavelength band of about 370 nm to about 460 nm, the green wavelength band may indicate that a main peak wavelength of light is included in a wavelength band of about 480 nm to about 560 nm, and the red wavelength band may indicate that a main peak wavelength of light is included in a wavelength band of about 600 nm to about 750 nm.

Although each of the pixels PX includes three emission areas EA1 through EA3 in FIGS. 5 and 6, embodiments of the specification are not limited thereto. For example, each of the pixels PX may also include four emission areas.

In addition, the arrangement of the emission areas of the pixels PX is not limited to those illustrated in FIGS. 5 and 6. For example, the emission areas of the pixels PX may also be arranged in a stripe structure in which emission areas are arranged in the first direction DR1, in a PenTile® structure in which emission areas are arranged in a diamond shape, or in a hexagonal structure in which emission areas having a hexagonal planar shape are arranged as illustrated in FIG. 6.

FIG. 7 is a schematic cross-sectional view of an example of the display panel 100, taken along line I1-I1′ of FIG. 5.

Referring to FIG. 7, the display panel 100 may include a semiconductor backplane SBP, a light emitting element backplane EBP, a display element layer EML, an encapsulation layer TFE, an inorganic layer APL, a cover layer CVL, and a polarizer POL.

The semiconductor backplane SBP may include a semiconductor substrate SSUB including pixel transistors PTR, semiconductor insulating layers covering the pixel transistors PTR, and contact terminals CTE electrically connected to each of the pixel transistors PTR. The pixel transistors PTR may be the first through sixth transistors T1 through T6 described with reference to FIG. 3.

The semiconductor substrate SSUB may be a silicon substrate, a germanium substrate, or a silicon-germanium substrate. The semiconductor substrate SSUB may be a substrate doped with a first-type impurity. Well areas WA may be disposed in an upper surface of the semiconductor substrate SSUB. The well areas WA may be areas doped with a second-type impurity. The second-type impurity may be different from the first-type impurity described above. For example, in case that the first-type impurity is a p-type impurity, the second-type impurity may be an n-type impurity. In other embodiments, in case that the first-type impurity is an n-type impurity, the second-type impurity may be a p-type impurity.

Each of the well areas WA may include a source area SA corresponding to a source electrode of a pixel transistor PTR, a drain area DA corresponding to a drain electrode of the pixel transistor PTR, and a channel area CH disposed between the source area SA and the drain area DA.

A bottom insulating layer BINS may be disposed between a gate electrode GE and each well area WA. A side insulating layer SINS may be disposed on side surfaces of the gate electrode GE. The side insulating layer SINS may be disposed on the bottom insulating layer BINS.

Each of the source area SA and the drain area DA may be an area doped with the first-type impurity. The gate electrode GE of each pixel transistor PTR may overlap a well area WA in the third direction DR3. The channel area CH may overlap the gate electrode GE in the third direction DR3. The source area SA may be disposed on a side of the gate electrode GE, and the drain area DA may be disposed on another side of the gate electrode GE.

Each of the well areas WA may further include a first lightly doped impurity area LDD1 disposed between the channel area CH and the source area SA and a second lightly doped impurity area LDD2 disposed between the channel area CH and the drain area DA. The first lightly doped impurity area LDD1 may be an area having a lower impurity concentration than the source area SA due to the bottom insulating layer BINS. The second lightly doped impurity area LDD2 may be an area having a lower impurity concentration than the drain area DA due to the bottom insulating layer BINS. A distance between the source area SA and the drain area DA may be increased by the first lightly doped impurity area LDD1 and the second lightly doped impurity area LDD2. Accordingly, a length of the channel area CH of each pixel transistor PTR may increase, thereby preventing punch-through and hot carrier phenomena caused by a short channel.

A first semiconductor insulating layer SINS1 may be disposed on the semiconductor substrate SSUB. The first semiconductor insulating layer SINS1 may be a silicon carbon nitride (SiCN) or silicon oxide (SiOx)-based inorganic layer, but embodiments of the specification are not limited thereto.

A second semiconductor insulating layer SINS2 may be disposed on the first semiconductor insulating layer SINS1. The second semiconductor insulating layer SINS2 may be a silicon oxide (SiOx)-based inorganic layer, but embodiments of the specification are not limited thereto.

The contact terminals CTE may be disposed on the second semiconductor insulating layer SINS2. Each of the contact terminals CTE may be connected to any one of the gate electrode GE, the source area SA, and the drain area DA of a pixel transistor PTR through a hole penetrating the first semiconductor insulating layer SINS1 and the second semiconductor insulating layer SINS2. The contact terminals CTE may be made of at least one of copper (Cu), aluminum (Al), tungsten (W), molybdenum (Mo), chromium (Cr), gold (Au), titanium (Ti), nickel (Ni) and neodymium (Nd) or may be made of an alloy including at least one of the same.

A third semiconductor insulating layer SINS3 may be disposed on side surfaces of each of the contact terminals CTE. An upper surface of each of the contact terminals CTE may be exposed without being covered by the third semiconductor insulating layer SINS3. The third semiconductor insulating layer SINS3 may be a silicon oxide (SiOx)-based inorganic layer, but embodiments of the specification are not limited thereto.

The semiconductor substrate SSUB can be replaced with a glass substrate or a polymer resin substrate such as polyimide. In this case, thin-film transistors may be disposed on the glass substrate or the polymer resin substrate. The glass substrate may be a rigid substrate that is not bent, and the polymer resin substrate may be a flexible substrate that can be bent or curved.

The light emitting element backplane EBP may include conductive layers ML1 through ML8, vias VA1 through VA9, and insulating layers INS1 through INS9. In addition, the light emitting element backplane EBP may include the insulating layers INS1 through INS9 disposed between first through eighth conductive layers ML1 through ML8.

The first through eighth conductive layers ML1 through ML8 may implement the circuit of the first subpixel SP1 illustrated in FIG. 3 by connecting the contact terminals CTE exposed in the semiconductor backplane SBP. For example, the first through sixth transistors T1 through T6 may only be formed in the semiconductor backplane SBP, and the connection of the first through sixth transistors T1 through T6 and the first and second capacitors CP1 and CP2 may be achieved through the first through eighth conductive layers ML1 through ML8. In addition, the connection between a drain area corresponding to the drain electrode of the fourth transistor T4, a source area corresponding to the source electrode of the fifth transistor T5, and the first electrode of the light emitting element LE may be achieved through the first through eighth conductive layers ML1 through ML8.

A first insulating layer INS1 may be disposed on the semiconductor backplane SBP. Each of first vias VA1 may penetrate the first insulating layer INS1 and may be connected to a contact terminal CTE exposed in the semiconductor backplane SBP. Each of the first conductive layers ML1 may be disposed on the first insulating layer INS1 and may be connected to a first via VA1.

A second insulating layer INS2 may be disposed on the first insulating layer INS1 and the first conductive layers ML1. Each of second vias VA2 may penetrate the second insulating layer INS2 and may be connected to an exposed first conductive layer ML1. Each of the second conductive layers ML2 may be disposed on the second insulating layer INS2 and may be connected to a second via VA2.

A third insulating layer INS3 may be disposed on the second insulating layer INS2 and the second conductive layers ML2. Each of third vias VA3 may penetrate the third insulating layer INS3 and may be connected to an exposed second conductive layer ML2. Each of the third conductive layers ML3 may be disposed on the third insulating layer INS3 and may be connected to a third via VA3.

A fourth insulating layer INS4 may be disposed on the third insulating layer INS3 and the third conductive layers ML3. Each of fourth vias VA4 may penetrate the fourth insulating layer INS4 and may be connected to an exposed third conductive layer ML3. Each of the fourth conductive layers ML4 may be disposed on the fourth insulating layer INS4 and may be connected to a fourth via VA4.

A fifth insulating layer INS5 may be disposed on the fourth insulating layer INS4 and the fourth conductive layers ML4. Each of fifth vias VA5 may penetrate the fifth insulating layer INS5 and may be connected to an exposed fourth conductive layer ML4. Each of the fifth conductive layers ML5 may be disposed on the fifth insulating layer INS5 and may be connected to a fifth via VA5.

A sixth insulating layer INS6 may be disposed on the fifth insulating layer INS5 and the fifth conductive layers ML5. Each of sixth vias VA6 may penetrate the sixth insulating layer INS6 and may be connected to an exposed fifth conductive layer ML5. Each of the sixth conductive layers ML6 may be disposed on the sixth insulating layer INS6 and may be connected to a sixth via VA6.

A seventh insulating layer INS7 may be disposed on the sixth insulating layer INS6 and the sixth conductive layers ML6. Each of seventh vias VA7 may penetrate the seventh insulating layer INS7 and may be connected to an exposed sixth conductive layer ML6. Each of the seventh conductive layers ML7 may be disposed on the seventh insulating layer INS7 and may be connected to a seventh via VA7.

An eighth insulating layer INS8 may be disposed on the seventh insulating layer INS7 and the seventh conductive layers ML7. Each of eighth vias VA8 may penetrate the eighth insulating layer INS8 and may be connected to an exposed seventh conductive layer ML7. Each of the eighth conductive layers ML8 may be disposed on the eighth insulating layer INS8 and may be connected to an eighth via VA8.

The first through eighth conductive layers ML1 through ML8 and the first through eighth vias VA1 through VA8 may be made of substantially the same material. The first through eighth conductive layers ML1 through ML8 and the first through eighth vias VA1 through VA8 may be made of at least one of copper (Cu), aluminum (Al), tungsten (W), molybdenum (Mo), chromium (Cr), gold (Au), titanium (Ti), nickel (Ni) and neodymium (Nd) or may be made of an alloy including at least one of the same. The first through eighth vias VA1 through VA8 may be made of substantially the same material. Each of the first through eighth insulating layers INS1 through INS8 may be a silicon oxide (SiOx)-based inorganic layer, but embodiments of the specification are not limited thereto.

A thickness of the first conductive layers ML1, a thickness of the second conductive layers ML2, a thickness of the third conductive layers ML3, a thickness of the fourth conductive layers ML4, a thickness of the fifth conductive layers ML5, and a thickness of the sixth conductive layers ML6 may each be greater than each of a thickness of the first vias VA1, a thickness of the second vias VA2, a thickness of the third vias VA3, a thickness of the fourth vias VA4, a thickness of the fifth vias VA5, and a thickness of the sixth vias VA6. The thickness of the second conductive layers ML2, the thickness of the third conductive layers ML3, the thickness of the fourth conductive layers ML4, the thickness of the fifth conductive layers ML5, and the thickness of the sixth conductive layers ML6 may each be greater than the thickness of the first conductive layers ML1. The thickness of the second conductive layers ML2, the thickness of the third conductive layers ML3, the thickness of the fourth conductive layers ML4, the thickness of the fifth conductive layers ML5, and the thickness of the sixth conductive layers ML6 may be substantially the same. For example, the thickness of the first conductive layers ML1 may be about 1360 Å, and the thickness of the second conductive layers ML2, the thickness of the third conductive layers ML3, the thickness of the fourth conductive layers ML4, the thickness of the fifth conductive layers ML5, and the thickness of the sixth conductive layers ML6 may each be about 1440 Å. In addition, the thickness of the first vias VA1, the thickness of the second vias VA2, the thickness of the third vias VA3, the thickness of the fourth vias VA4, the thickness of the fifth vias VA5, and the thickness of the sixth vias VA6 may each be about 1150 Å.

A thickness of the seventh conductive layers ML7 and a thickness of the eighth conductive layers ML8 may each be greater than each of the thickness of the first conductive layers ML1, the thickness of the second conductive layers ML2, the thickness of the third conductive layers ML3, the thickness of the fourth conductive layers ML4, the thickness of the fifth conductive layers ML5, and the thickness of the sixth conductive layer ML6. The thickness of the seventh conductive layers ML7 and the thickness of the eighth conductive layers ML8 may each be greater than each of a thickness of the seventh vias VA7 and a thickness of the eighth vias VA8. The thickness of the seventh vias VA7 and the thickness of the eighth vias VA8 may each be greater than each of the thickness of the first vias VA1, the thickness of the second vias VA2, the thickness of the third vias VA3, the thickness of the fourth vias VA4, the thickness of the fifth vias VA5, and the thickness of the sixth vias VA6. The thickness of the seventh conductive layers ML7 and the thickness of the eighth conductive layers ML8 may be substantially the same. For example, the thickness of the seventh conductive layers ML7 and the thickness of the eighth conductive layers ML8 may each be about 9000 Å. The thickness of the seventh vias VA7 and the thickness of the eighth vias VA8 may each be about 6000 Å.

A ninth insulating layer INS9 may be disposed on the eighth insulating layer INS8 and the eighth conductive layers ML8. The ninth insulating layer INS9 may be a silicon oxide (SiOx)-based inorganic layer, but embodiments of the specification are not limited thereto.

Each of ninth vias VA9 may penetrate the ninth insulating layer INS9 and may be connected to an exposed eighth conductive layer ML8. The ninth vias VA9 may be made of at least one of copper (Cu), aluminum (Al), tungsten (W), molybdenum (Mo), chromium (Cr), gold (Au), titanium (Ti), nickel (Ni) and neodymium (Nd) or may be made of an alloy including at least one of the same. A thickness of the ninth vias VA9 may be about 16500 Å.

The display element layer EML may be disposed on the light emitting element backplane EBP. The display element layer EML may include a reflective electrode layer RL, tenth and eleventh insulating layers INS10 and INS11, tenth vias VA10, light emitting elements LE, each including a first electrode AND, a light emitting stack IL and a second electrode CAT, and a pixel defining layer PDL.

The reflective electrode layer RL may be disposed on the ninth insulating layer INS9. The reflective electrode layer RL may include one or more reflective electrodes RL1 through RL4. For example, the reflective electrode layer RL may include first through fourth reflective electrodes RL1 through RL4 as illustrated in FIG. 7.

Each of the first reflective electrodes RL1 may be disposed on the ninth insulating layer INS9 and may be connected to a ninth via VA9. The first reflective electrodes RL1 may be made of at least one of copper (Cu), aluminum (Al), tungsten (W), molybdenum (Mo), chromium (Cr), gold (Au), titanium (Ti), nickel (Ni) and neodymium (Nd) or may be made of an alloy including at least one of the same. For example, the first reflective electrodes RL1 may include titanium nitride (TiN).

Each of the second reflective electrodes RL2 may be disposed on a first reflective electrode RL1. The second reflective electrodes RL2 may be made of at least one of copper (Cu), aluminum (Al), tungsten (W), molybdenum (Mo), chromium (Cr), gold (Au), titanium (Ti), nickel (Ni) and neodymium (Nd) or may be made of an alloy including at least one of the same. For example, the second reflective electrodes RL2 may include aluminum (Al).

Each of the third reflective electrodes RL3 may be disposed on a second reflective electrode RL2. The third reflective electrodes RL3 may be made of at least one of copper (Cu), aluminum (Al), tungsten (W), molybdenum (Mo), chromium (Cr), gold (Au), titanium (Ti), nickel (Ni) and neodymium (Nd) or may be made of an alloy including at least one of the same. For example, the third reflective electrodes RL3 may include titanium nitride (TiN).

Each of the fourth reflective electrodes RL4 may be disposed on a third reflective electrode RL3. The fourth reflective electrodes RL4 may be made of at least one of copper (Cu), aluminum (Al), tungsten (W), molybdenum (Mo), chromium (Cr), gold (Au), titanium (Ti), nickel (Ni) and neodymium (Nd) or may be made of an alloy including at least one of the same. For example, the fourth reflective electrodes RL4 may include titanium (Ti).

Since the second reflective electrodes RL2 are electrodes that substantially reflect light from the light emitting elements LE, a thickness of the second reflective electrodes RL2 may be greater than a thickness of the first reflective electrodes RL1, a thickness of the third reflective electrodes RL3, and a thickness of the fourth reflective electrodes RL4. For example, the thickness of the first reflective electrodes RL1, the thickness of the third reflective electrodes RL3 and the thickness of the fourth reflective electrodes RL4 may be about 100 Å, and the thickness of the second reflective electrodes RL2 may be about 850 Å.

The tenth insulating layer INS10 may be disposed on the ninth insulating layer INS9. The tenth insulating layer INS10 may be disposed between reflective electrode layers RL adjacent to each other in a horizontal direction. The tenth insulating layer INS10 may be a silicon oxide (SiOx)-based inorganic layer, but embodiments of the specification are not limited thereto.

The eleventh insulating layer INS11 may be disposed on the tenth insulating layer INS10 and the reflective electrode layer RL. The eleventh insulating layer INS11 may be a silicon oxide (SiOx)-based inorganic layer, but embodiments of the specification are not limited thereto. The tenth insulating layer INS10 and the eleventh insulating layer INS11 may be optical auxiliary layers through which light reflected by the reflective electrode layer RL among light emitted from the light emitting elements LE passes.

The tenth insulating layer INS10 or the eleventh insulating layer INS11 may not be disposed under the first electrode AND of at least any one of the first subpixel SP1, a second subpixel SP2, and the third subpixel SP3 in order to match resonance distances of light emitted from the light emitting elements LE. For example, the first electrode AND of the first subpixel SP1 may be directly disposed on the reflective electrode layer RL. The eleventh insulating layer INS11 may be disposed under the first electrode AND of the second subpixel SP2. The tenth insulating layer INS10 and the eleventh insulating layer INS11 may be disposed under the first electrode AND of the third subpixel SP3.

In summary, a distance between the first electrode AND and the reflective electrode layer RL may be different in each of the first subpixel SP1, the second subpixel SP2, and the third subpixel SP3. That is, the presence or absence of the tenth insulating layer INS10 and the eleventh insulating layer INS11 in each of the first subpixel SP1, the second subpixel SP2, and the third subpixel SP3 may be set in order to adjust the distance from the reflective electrode layer RL to the first electrode AND according to the main wavelength of light emitted from each of the first subpixel SP1, the second subpixel SP2, and the third subpixel SP3. For example, a distance between the first electrode AND and the reflective electrode layer RL in the third subpixel SP3 may be greater than a distance between the first electrode AND and the reflective electrode layer RL in the second subpixel SP2 and a distance between the first electrode AND and the reflective electrode layer RL in the first subpixel SP1, and the distance between the first electrode AND and the reflective electrode layer RL in the second subpixel SP2 may be greater than the distance between the first electrode AND and the reflective electrode layer RL in the first subpixel SP1. However, embodiments of the specification are not limited thereto.

In addition, although the tenth insulating layer INS10 and the eleventh insulating layer INS11 are shown as examples in embodiments of the specification, a twelfth insulating layer disposed under the first electrode AND of the first subpixel SP1 may also be added. In this case, the eleventh insulating layer INS11 and the twelfth insulating layer may be disposed under the first electrode AND of the second subpixel SP2, and the tenth insulating layer INS10, the eleventh insulating layer INS11 and the twelfth insulating layer may be disposed under the first electrode AND of the third subpixel SP3.

The tenth vias VA10 may penetrate the tenth insulating layer INS10 and/or the eleventh insulating layer INS11 in the second subpixel SP2 and the third subpixel SP3 and may be connected to exposed ninth conductive layers ML8, respectively. The tenth vias VA10 may be made of at least one of copper (Cu), aluminum (Al), tungsten (W), molybdenum (Mo), chromium (Cr), gold (Au), titanium (Ti), nickel (Ni) and neodymium (Nd) or may be made of an alloy including at least one of the same. A thickness of a tenth via VA10 in the second subpixel SP2 may be smaller than a thickness of a tenth via VA10 in the third subpixel SP3.

The first electrode AND of each of the light emitting elements LE may be disposed on the tenth insulating layer INS10 and may be connected to a tenth via VA10. The first electrode AND of each of the light emitting elements LE may be connected to the drain area DA or the source area SA of a pixel transistor PTR through a tenth via VA10, the first through fourth reflective electrodes RL1 through RL4, the first through ninth vias VA1 through VA9, the first through eighth conductive layers ML1 through ML8, and a contact terminal CTE. The first electrode AND of each of the light emitting elements LE may be made of at least one of copper (Cu), aluminum (Al), tungsten (W), molybdenum (Mo), chromium (Cr), gold (Au), titanium (Ti), nickel (Ni) and neodymium (Nd) or may be made of an alloy including at least one of the same. For example, the first electrode AND of each of the light emitting elements LE may be titanium nitride (TiN).

The pixel defining layer PDL may be disposed on a portion of the first electrode AND of each of the light emitting elements LE. The pixel defining layer PDL may cover edges of the first electrode AND of each of the light emitting elements LE. The pixel defining layer PDL may define first through third emission areas EA1 through EA3.

The first emission area EA1 may be defined as an area in the first subpixel SP1 where the first electrode AND, the light emitting stack IL, and the second electrode CAT are stacked on each other to emit light. The second emission area EA2 may be defined as an area in the second subpixel SP2 where the first electrode AND, the light emitting stack IL, and the second electrode CAT are stacked on each other to emit light. The third emission area EA3 may be defined as an area in the third subpixel SP3 where the first electrode AND, the light emitting stack IL, and the second electrode CAT are stacked on each other to emit light.

The pixel defining layer PDL may include first through third pixel defining layers PDL1 through PDL3. The first pixel defining layer PDL1 may be disposed on the edges of the first electrode AND of each of the light emitting elements LE. The second pixel defining layer PDL2 may be disposed on the first pixel defining layer PDL1. The third pixel defining layer PDL3 may be disposed on the second pixel defining layer PDL2. Each of the first pixel defining layer PDL1, the second pixel defining layer PDL2, and the third pixel defining layer PDL3 may be a silicon oxide (SiOx)-based inorganic layer, but embodiments of the specification are not limited thereto. A thickness of the first pixel defining layer PDL1, a thickness of the second pixel defining layer PDL2, and a thickness of the third pixel defining layer PDL3 may each be about 500 Å.

In case that the first pixel defining layer PDL1, the second pixel defining layer PDL2, and the third pixel defining layer PDL3 are formed as a single pixel defining layer, a height of the single pixel defining layer may increase, causing a first encapsulating inorganic layer TFE1 to be broken due to step coverage. The step coverage refers to the ratio of the extent to which a thin film is applied on an inclined portion to the extent to which the thin film is applied on a flat portion. The lower the step coverage, the higher the probability that the thin film will break in the inclined portion.

Therefore, in order to prevent the first encapsulating inorganic layer TFE1 from being broken due to the step coverage, the first pixel defining layer PDL1, the second pixel defining layer PDL2, and the third pixel defining layer PDL3 may have a cross-sectional structure having steps. For example, a width of the first pixel defining layer PDL1 may be greater than a width of the second pixel defining layer PDL2 and a width of the third pixel defining layer PDL3, and the width of the second pixel defining layer PDL2 may be greater than the width of the third pixel defining layer PDL3. The width of the first pixel defining layer PDL1 refers to a horizontal length of the first pixel defining layer PDL1 defined by the first direction DR1 and the second direction DR2.

The light emitting stack IL may include intermediate layers. The light emitting stack IL may include a first stack layer IL1, a second stack layer IL2, and a third stack layer IL3 that emit different lights. The first stack layer IL1, the second stack layer IL2, and the third stack layer IL3 may be broken without being continuously connected between neighboring subpixels.

The first stack layer IL1 may have a structure in which a first hole transport layer, a first organic light emitting layer emitting light of the first color, and a first electron transport layer are stacked on each other. The first stack layer IL1 may be disposed on the first electrodes AND and the pixel defining layer PDL in the first emission area EA1 of the first subpixel SP1.

The second stack layer IL2 may have a structure in which a second hole transport layer, a second organic light emitting layer emitting light of the third color, and a second electron transport layer are stacked on each other. The second stack layer IL2 may be disposed on the first electrodes AND and the pixel defining layer PDL in the second emission area EA2 of the second subpixel SP2.

The third stack layer IL3 may have a structure in which a third hole transport layer, a third organic light emitting layer emitting light of the second color, and a third electron transport layer are stacked on each other. The third stack layer IL3 may be disposed on the first electrodes AND and the pixel defining layer PDL in the third emission area EA3 of the third subpixel SP3.

The second electrode CAT may be disposed on the third stack layer IL3 and the pixel defining layer PDL. The second electrode CAT may be made of a transparent conductive material (TCO) that can transmit light, such as indium tin oxide (ITO) or indium zinc oxide (IZO), or a semi-transmissive conductive material such as magnesium (Mg), silver (Ag) or an alloy of Mg and Ag. In case that the second electrode CAT is made of a semi-transmissive conductive material, the light output efficiency of each of the first through third subpixels SP1 through SP3 may be increased by a microcavity.

The encapsulation layer TFE may be disposed on the display element layer EML. The encapsulation layer TFE may include one or more inorganic layers TFE1 and TFE2 to prevent the penetration of oxygen or moisture into the display element layer EML. For example, the encapsulation layer TFE may include the first encapsulating inorganic layer TFE1 and a second encapsulating inorganic layer TFE2.

The first encapsulating inorganic layer TFE1 may be disposed on the second electrode CAT. The first encapsulating inorganic layer TFE1 may be a multilayer in which one or more inorganic layers selected from silicon nitride (SiNx), silicon oxynitride (SiON), and silicon oxide (SiOx) are stacked on each other. The first encapsulating inorganic layer TFE1 may be formed by a chemical vapor deposition (CVD) process.

The second encapsulating inorganic layer TFE2 may be disposed on the first encapsulating inorganic layer TFE1. The second encapsulating inorganic layer TFE2 may be a titanium oxide (TiOx) or aluminum oxide (AlOx) layer, but embodiments of the specification are not limited thereto. The second encapsulating inorganic layer TFE2 may be formed by an atomic layer deposition (ALD) process. A thickness of the second encapsulating inorganic layer TFE2 may be smaller than a thickness of the first encapsulating inorganic layer TFE1.

An organic layer APL may be a layer for increasing the interfacial adhesion between the encapsulation layer TFE and the cover layer CVL. The organic layer APL may be an organic layer such as acryl resin, epoxy resin, phenolic resin, polyamide resin, or polyimide resin.

The cover layer CVL may be disposed on the organic layer APL. The cover layer CVL may be a glass substrate or a polymer resin such as resin.

The polarizer POL may be disposed on a surface of the cover layer CVL. The polarizer POL may be a structure for preventing visibility reduction due to the reflection of external light. The polarizer POL may include a linear polarizer and a phase retardation film. For example, the phase retardation film may be a quarter-wave plate (λ/4 plate), but embodiments of the specification are not limited thereto.

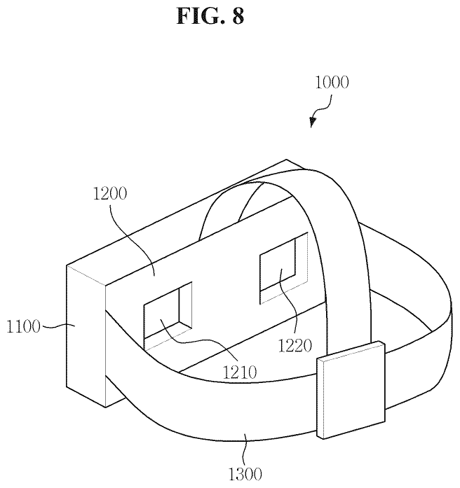

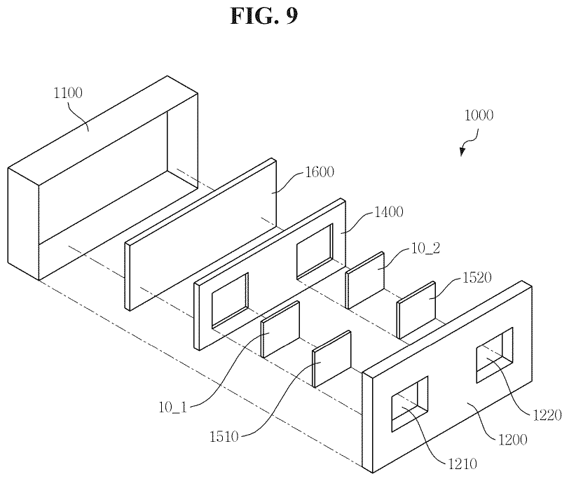

FIG. 8 is a schematic perspective view of a head mounted display device 1000 according to an embodiment. FIG. 9 is an exploded schematic perspective view of an example of the head mounted display device 1000 of FIG. 8.

Referring to FIGS. 8 and 9, the head mounted display device 1000 according to an embodiment may include a first display device 10_1, a second display device 10_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_1 may provide an image to a user's left eye, and the second display device 10_2 provides an image to the user's right eye. Each of the first display device 10_1 and the second display device 10_2 is substantially the same as the display device 10 described with reference to FIGS. 1 and 2. Therefore, a description of the first display device 10_1 and the second display device 10_2 will be omitted.

The first optical member 1510 may be disposed between the first display device 10_1 and the first eyepiece 1210. The second optical member 1520 may be disposed between the second display device 10_2 and the second eyepiece 1220. Each of the first optical member 1510 and the second optical member 1520 may include at least one convex lens.

The middle frame 1400 may be disposed between the first display device 10_1 and the control circuit board 1600 and may be disposed between the second display device 10_2 and the control circuit board 1600. The middle frame 1400 may support and secure the first display device 10_1, the second display device 10_2, and the control circuit board 1600.

The control circuit board 1600 may be disposed between the middle frame 1400 and the display device housing 1100. The control circuit board 1600 may be connected to the first display device 10_1 and the second display device 10_2 through a connector. The control circuit board 1600 may convert an image source received from the outside into digital video data DATA and transmit the digital video data DATA to the first display device 10_1 and the second display device 10_2 through the connector.

The control circuit board 1600 may transmit the digital video data DATA corresponding to a left image optimized for a user's left eye to the first display device 10_1 and transmit the digital video data DATA corresponding to a right image optimized for the user's right eye to the second display device 10_2. In other embodiments, the control circuit board 1600 may transmit the same digital video data DATA to the first display device 10_1 and the second display device 10_2.

The display device housing 1100 houses the first display device 10_1, the second display device 10_2, the middle frame 1400, the first optical member 1510, the second optical member 1520, and the control circuit board 1600. The housing cover 1200 is placed to cover an open surface of the display device housing 1100. The housing cover 1200 may include the first eyepiece 1210 on which a user's left eye is placed and the second eyepiece 1220 on which the user's right eye is placed. Although the first eyepiece 1210 and the second eyepiece 1220 are disposed separately in FIGS. 8 and 9, embodiments of the specification are not limited thereto. The first eyepiece 1210 and the second eyepiece 1220 may also be combined into one.

The first eyepiece 1210 may be aligned with the first display device 10_1 and the first optical member 1510, and the second eyepiece 1220 may be aligned with the second display device 10_2 and the second optical member 1520. Therefore, a user can view an image of the first display device 10_1, which is enlarged as a virtual image by the first optical member 1510, through the first eyepiece 1210 and can view an image of the second display device 10_2, which is enlarged as a virtual image by the second optical member 1520, through the second eyepiece 1220.

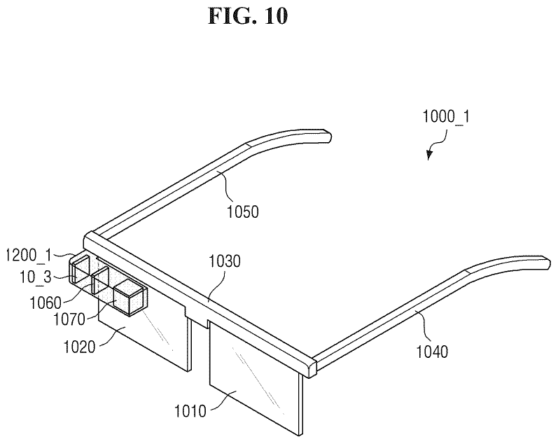

The head mounted band 1300 may secure the display device housing 1100 to a user's head so that the first eyepiece 1210 and the second eyepiece 1220 of the housing cover 1200 are kept placed on the user's left and right eyes, respectively. In case that the display device housing 1200 is implemented to be lightweight and small, the head mounted display device 1000 may include an eyeglass frame as illustrated in FIG. 10 instead of the head mounted band 1300.

In addition, the head mounted display device 1000 may further include a battery for supplying power, an external memory slot for accommodating an external memory, and an external connection port and a wireless communication module for receiving an image source. The external connection port may be a universal serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 10 is a schematic perspective view of a head mounted display device 1000_1 according to an embodiment.

Referring to FIG. 10, the head mounted display device 1000_1 according to an embodiment may be a display device in the form of glasses in which a display device housing 1200_1 is implemented to be lightweight and small. The head mounted display device 1000_1 according to an embodiment may include a display device 10_3, a left lens 1010, a right lens 1020, a support frame 1030, eyeglass frame legs 1040 and 1050, an optical member 1060, an optical path conversion member 1070, and the display device housing 1200_1.

The display device housing 1200_1 may include the display device 10_3, the optical member 1060, and the optical path conversion member 1070. An image displayed on the display device 10_3 may be enlarged by the optical member 1060, may have its optical path converted by the optical path conversion member 1700, and may be provided to a user's right eye through the right lens 1020. Accordingly, the user can view, through the right eye, an augmented reality image into which a virtual image displayed on the display device 10_3 and a real image viewed through the right lens 1020 are combined.

Although the display device housing 1200_1 is disposed at a right end of the support frame 1030 in FIG. 10, embodiments of the specification are not limited thereto. For example, the display device housing 1200_1 may also be disposed at a left end of the support frame 1030. In this case, an image of the display device 10_3 may be provided to a user's left eye. In other embodiments, the display device housing 1200_1 may be disposed at both the left and right ends of the support frame 1030. In this case, the user can view an image displayed on the display device 10_3 through both the left and right eyes.

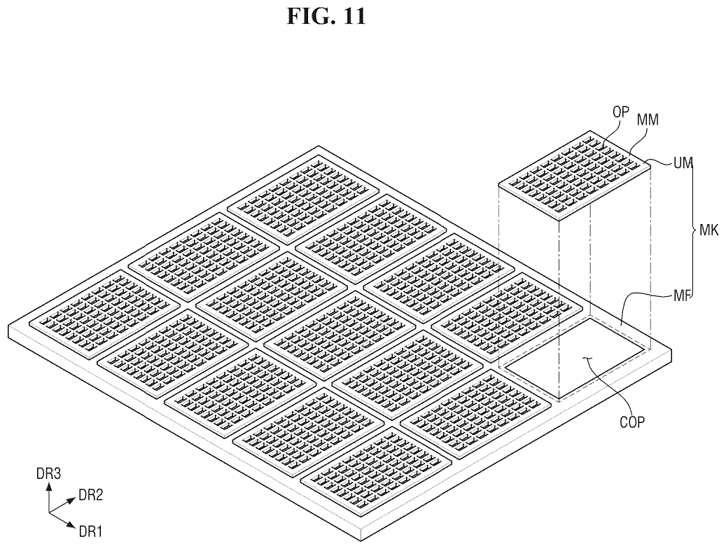

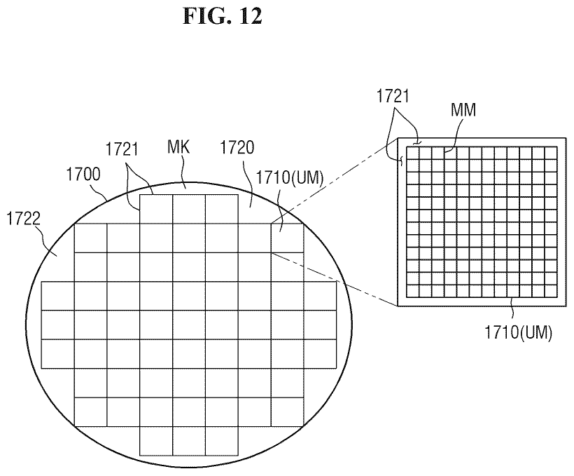

FIG. 11 is a schematic perspective view of a mask MK according to an embodiment. FIG. 12 is a schematic plan view of the mask MK according to an embodiment. FIG. 11 is a perspective view illustrating a state in which one unit mask UM is separated from unit masks. The mask MK according to an embodiment illustrated in FIGS. 11 and 12 may be used in a process of depositing at least a portion of the light emitting stack IL described with reference to FIG. 7. For example, the light emitting stack IL may be configured to emit light of different colors in the subpixels SP1 through SP3.

Referring to FIGS. 11 and 12, the mask MK according to an embodiment may be a shadow mask in which a mask membrane MM is disposed on a silicon substrate 1700. The mask MK according to an embodiment may be referred to as a “silicon mask.”

According to an embodiment, the mask MK may include the silicon substrate 1700, and the mask membrane MM may be disposed on the silicon substrate 1700. The mask membrane MM may be disposed in cell areas 1710 arranged in a matrix form, and each cell area 1710 may be surrounded by a mask rib area 1721. A portion of the silicon substrate 1700 may be disposed in the mask rib area 1721, and the mask rib area 1721 may support the mask membrane MM.

The mask membrane MM may be a part of a unit mask UM disposed in each of the cell areas 1710.

The silicon substrate 1700 may include cell areas 1710 and a mask frame area 1720 excluding the cell areas 1710. The mask frame area 1720 may include the mask rib area 1721 surrounding each cell area 1710 and an outer frame area 1722 disposed at an outermost periphery of the silicon substrate 1700. A mask frame MF may be disposed in the mask frame area 1720. The mask frame MF may include mask ribs surrounding the cell areas 1710.

The mask rib area 1721 may be an area that separates the cell areas 1710. For example, the cell areas 1710 may be arranged in a matrix form, and mask ribs disposed in the mask rib area 1721 may surround the mask membrane MM disposed in each of the cell areas 1710.

A cell opening COP and a unit mask UM that masks at least a portion of the cell opening COP may be disposed in each of the cell areas 1710 of the silicon substrate 1700.

Multiple cell openings COP may penetrate the mask frame MF along the thickness direction (e.g., the third direction DR3) of the mask MK. Each of the cell openings COP may be formed by etching a portion of the silicon substrate 1700 from a back side.

Each unit mask UM may include the mask membrane MM, and the mask membrane MM may include mask openings OP.

The mask openings of the mask membrane MM may be referred to as “holes” or “mask holes”. The mask openings may penetrate the unit masks UM along the thickness direction (e.g., the third direction DR3) of the mask MK.

One unit mask UM may be used in a deposition process of one display panel 100. In the disclosure, the term “unit mask UM” can be replaced with a term such as “mask unit UM” or “unit mask UM”.

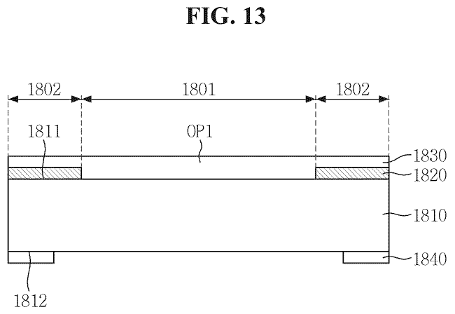

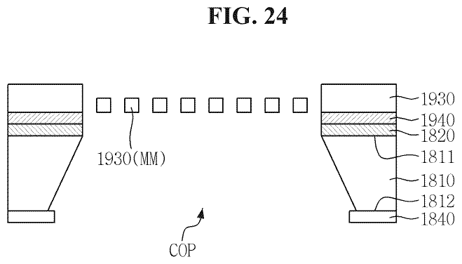

FIGS. 13 through 24 are schematic cross-sectional views illustrating a method of manufacturing a mask according to an embodiment. For example, FIG. 24 may be a cross-sectional view of a portion of a mask according to an embodiment, and FIGS. 13 through 24 may be views for sequentially explaining a process of manufacturing the mask illustrated in FIG. 24.

The method of manufacturing the mask according to an embodiment will now be described with reference to FIGS. 13 through 24.

Referring to FIG. 13, a first substrate 1810 may be prepared. The first substrate 1810 may include silicon (Si). The first substrate 1810 may, but not necessarily, be referred to as a body substrate.

In case of preparing the first substrate 1810, a first metal layer may be deposited on a front surface 1811 of the first substrate 1810. The deposited first metal layer may be patterned to form a first opening OP1 of the first metal layer and a first bonding portion 1820 of the first metal layer. The first metal layer may also be referred to as a first bonding metal. The first opening OP1 of the first metal layer may be an area that ultimately becomes a cell opening COP after the mask manufacturing process is completed. The first bonding portion 1820 of the first metal layer excluding the first opening OP1 may be an area that ultimately becomes a mask frame area 1720 after the mask manufacturing process is completed. For example, the first substrate 1810 may include a first area 1801 corresponding to the cell opening COP and a second area 1802 corresponding to the mask frame area 1720. FIG. 13 illustrates a process of forming the first bonding portion 1820 on the front surface 1811 of the first substrate 1810 corresponding to the second area 1802.

After the first metal layer is patterned, insulating layers 1830 and 1840 may be deposited on the front surface 1811 and a back surface 1812 of the first substrate 1810, respectively. The insulating layer 1830 deposited on the front surface 1811 of the first substrate 1810 may cover the first bonding portion 1820 and the first opening OP1 of the first metal layer. Of the insulating layer 1840 deposited on the back surface 1812 of the first substrate 1810, a portion corresponding to the first opening OP1 of the first metal layer may be removed by etching. Accordingly, the insulating layer 1840 on the back surface 1812 of the first substrate 1810 may remain only in an area overlapped by the first bonding portion 1820 of the first metal layer. Here, the insulating layers 1830 and 1840 may include at least one of silicon (Si), silicon nitride (SiNx), silicon oxynitride (SiON), silicon oxide (SiOx), titanium oxide (TiOx), amorphous silicon (a-Si), and aluminum oxide (AlOx) layers.

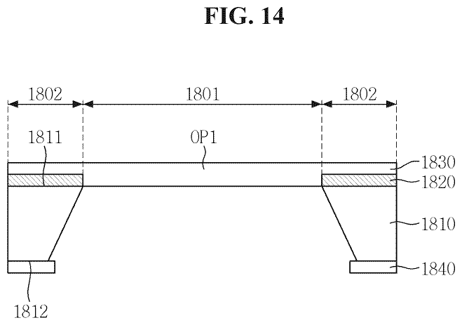

Referring to FIG. 14, the insulating layer 1830 deposited on the first area 1801 of the first substrate 1810 may be exposed by etching a portion of the first substrate 1810, which corresponds to the first opening OP1, from the back surface 1812 of the first substrate 1810. Here, a developer used to remove the first substrate 1810 may include tetramethylammonium hydroxide (TMAH) or potassium hydroxide (KOH).

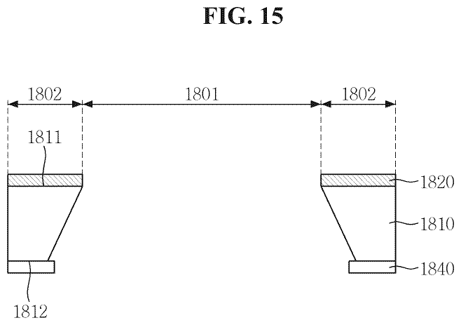

Referring to FIG. 15, the insulating layer 1830 deposited on the front surface 1811 of the first substrate 1810 may be removed. Accordingly, the cell opening COP1 exposing the first opening OP1 from the back surface 1812 of the first substrate 1810 may be formed. The insulating layer 1840 deposited on the back surface 1812 of the first substrate 1810 may remain.

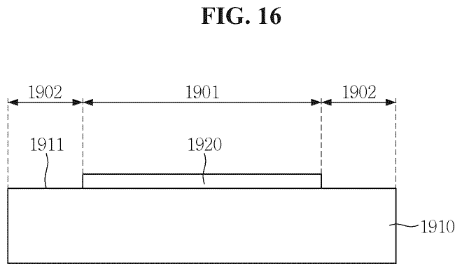

FIGS. 13 through 15 illustrate the process of preparing the first substrate 1810 and processing the prepared first substrate 1810. FIGS. 16 through 21 illustrate processes related to a second substrate 1910 to be bonded to the first substrate 1810 described in FIGS. 13 through 15.

Referring to FIG. 16, the second substrate 1910 may be prepared. The second substrate 1910 may include sapphire. The second substrate 1910 may, but not necessarily, be referred to as a membrane substrate. The material of the second substrate 1910 is not limited to sapphire. For example, the second substrate 1910 may also be “GaN on sapphire” or “GaN on Si”, instead of sapphire.

In case of preparing the second substrate 1910, a first inorganic layer may be deposited on a front surface 1911 of the second substrate 1910. The deposited first inorganic layer may be patterned to form a base layer 1920. The first inorganic layer may include ZnO. ZnO is a chemically stable and hard material and is therefore a suitable material for the first inorganic layer.

The second substrate 1910 may include a third area 1901 corresponding to the cell opening COP and a fourth area 1902 corresponding to the mask frame area 1720. FIG. 16 illustrates the process of depositing the first inorganic layer on the front surface 1911 of the second substrate 1910 which corresponds to the third area 1901.

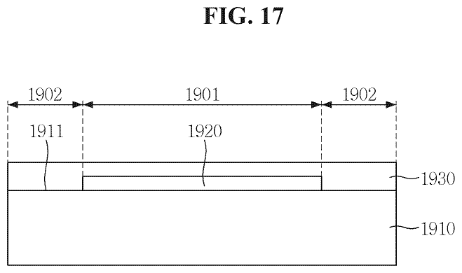

Referring to FIG. 17, a second inorganic layer 1930 may be deposited on the front surface 1911 of the second substrate 1910 including the base layer 1920. The second inorganic layer 1930 may include GaN. The second inorganic layer 1930 may cover the third area 1901 and the fourth area 1902 of the second substrate 1910. The second inorganic layer 1930 may be a material that ultimately becomes a mask membrane MM. GaN is a chemically stable material and is a material that is easy to deposit on a large area of about 8 to about 12 inches. Therefore, GaN is a suitable material for the second inorganic layer 1930.

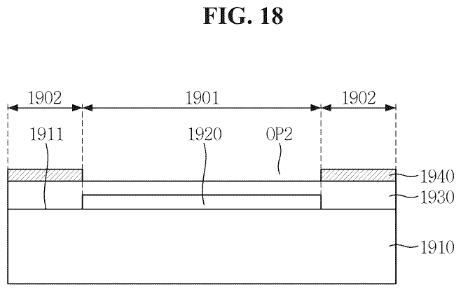

Referring to FIG. 18, a second metal layer may be deposited on the second inorganic layer 1930. The deposited second metal layer may be patterned to form a second opening OP2 of the second metal layer and a second bonding portion 1940 of the second metal layer. For example, the second bonding portion 1940 of the second metal layer may be disposed in the fourth area 1902, and the second opening OP2 may be disposed in the third area 1901.

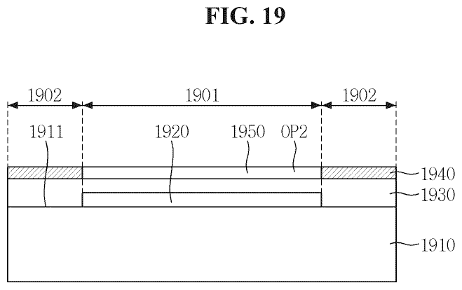

Referring to FIG. 19, an insulating layer may be deposited on the front surface 1911 of the second substrate 1910 including the second bonding portion 1940 and the second inorganic layer 1930. The deposited insulating layer may be patterned to form a protective layer 1950 covering the second insulating layer 1930 in the second opening OP2. Here, the insulating layer (i.e., the protective layer 1950) may include at least one of silicon (Si), silicon nitride (SiNx), silicon oxynitride (SiON), silicon oxide (SiOx), titanium oxide (TiOx), amorphous silicon (a-Si), and aluminum oxide (AlOx) layers.

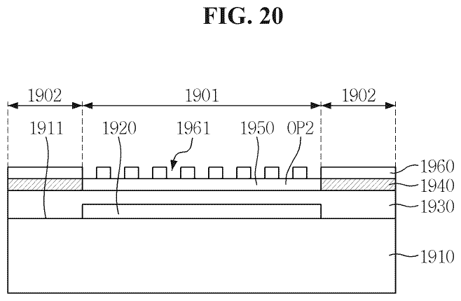

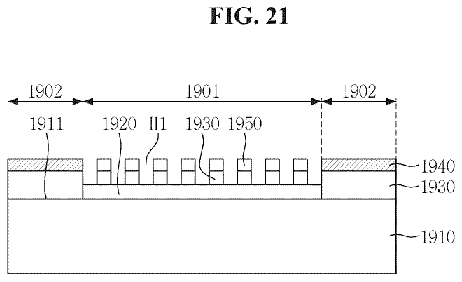

Referring to FIGS. 20 and 21, first grooves H1 penetrating the protective layer 1950 and the second inorganic layer 1930 may be formed in the second opening OP2.

For example, the forming of the first grooves H1 may include, as illustrated in FIG. 20, forming a photoresist pattern 1960 including the first grooves H1, which correspond to the second opening OP2, on the front surface 1911 of the second substrate 1910 including the second bonding portion 1940 and the protective layer 1950.

The forming of the first grooves H1 may include, as illustrated in FIG. 21, etching the protective layer 1950 and the second inorganic layer 1930 using the photoresist pattern 1960. After the second inorganic layer 1930 is etched, the photoresist pattern 1960 may be removed.

In case of removing the photoresist pattern 1960, the second inorganic layer 1930 and the protective layer 1950 patterned to include the first grooves H1 may remain deposited on the base layer 1920 in the third area 1901 of the second substrate 1910. The second inorganic layer 1930 remaining in the third area 1901 of the second substrate 1910 may ultimately become the mask membrane MM after the mask manufacturing process is completed, and each first groove H1 between neighboring second inorganic layers 1930 may become an opening of the mask membrane MM.

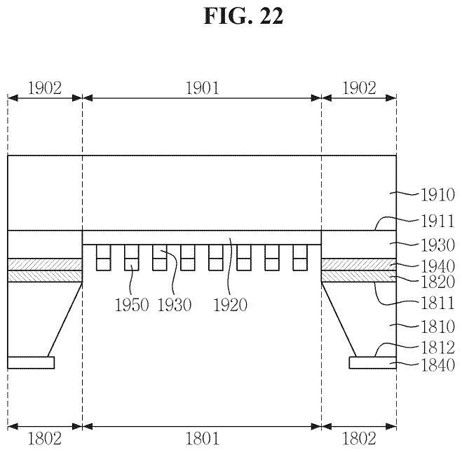

Referring to FIG. 22, the front surface 1811 of the first substrate 1810 and the front surface 1911 of the second substrate 1910 may be placed to face each other, and the first bonding portion 1820 and the second bonding portion 1940 may be bonded to each other. For example, FIG. 22 illustrates the process of bonding the first substrate 1810 of FIG. 15 and the second substrate 1910 of FIG. 21 to each other. The process of bonding different metal layers, that is, the process of bonding the first bonding portion 1820 and the second bonding portion 1940 to each other may be performed using bonding technology.

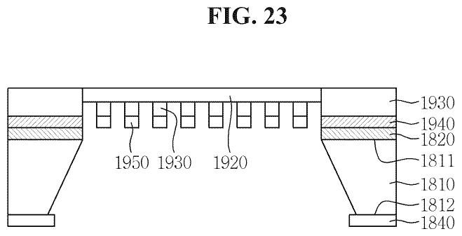

Referring to FIG. 23, the second substrate 1910 may be removed. The process of removing the second substrate 1910 may include a laser lift off (LLO) process. In case that the second substrate 1910 is removed, the base layer 1920 including the first inorganic layer may be exposed.

Referring to FIG. 24, the protective layer 1950 and the base layer 1920 which cover the second inorganic layer 1930 may be removed to expose the mask membrane MM including the second inorganic layer 1930 disposed in the cell opening COP. In addition, the insulating layer 1840 deposited on the back surface 1812 of the first substrate 1810 may be removed. The insulating layer 1840 deposited on the back surface 1812 of the first substrate 1810 may also not be removed.

As described above, the method of manufacturing the mask according to an embodiment of the disclosure can reduce the risk of the mask being damaged during the mask manufacturing process due to a thin thickness of the mask membrane. Therefore, the mask manufacturing yield can be increased.

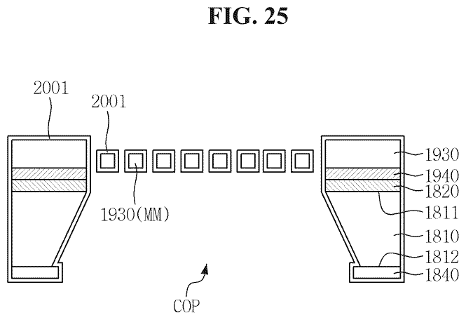

FIG. 25 is a schematic cross-sectional view of a mask for explaining a process of depositing a protective layer on the mask according to an embodiment.

Referring to FIG. 25, in the method of manufacturing the mask according to an embodiment, an insulating layer (e.g., a coating layer) may be formed on the entire surface of the mask in consideration of reuse of the mask. For example, the method of manufacturing the mask may further include forming a coating layer 2001 which covers the entire surface of the first substrate 1810 and the entire surface of the mask membrane using atomic layer deposition.

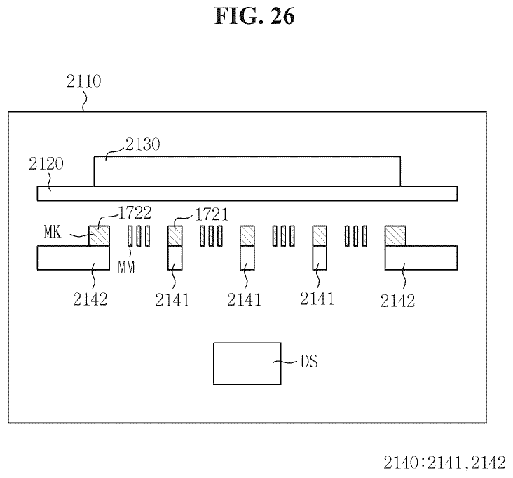

FIG. 26 schematically illustrates the configuration of deposition equipment according to an embodiment.

FIG. 26 is a configuration diagram of deposition equipment according to an embodiment.

Referring to FIG. 26, the deposition equipment according to an embodiment may include a chamber 2110, a deposition source DS disposed inside the chamber 2110, a mask MK disposed between a first substrate 2120 and the deposition source DS inside the chamber 2110, and a mask support 2140 disposed between the deposition source DS and the mask MK to support at least a portion of the mask MK.

According to an embodiment, the mask MK may include a mask membrane MM.

The first substrate 2120 illustrated in FIG. 26 may be the display panel 100 described with reference to FIGS. 1 through 7. Therefore, a description of the first substrate 2120 will be replaced with the description of the display panel 100 given with reference to FIGS. 1 through 7.

The mask support 2140 may be disposed under the mask MK to support and secure the mask MK. For example, the mask support 2140 may be configured as an electrostatic chuck. According to an embodiment, the mask support 2140 may include a first support area 2141 supporting a mask rib area 1721 of the mask MK and a second support area 2142 supporting an outer frame area 1722 of the mask MK.

Reference numeral 2130 in FIG. 26 indicates a fixing member 2130 for securing the first substrate 2120 and may be configured as, for example, an electrostatic chuck.

As illustrated in FIG. 26, a method of manufacturing a display device 10 using deposition equipment according to an embodiment may include the following operations. For example, the method of manufacturing the display device 10 according to an embodiment may include manufacturing a mask MK, placing a deposition substrate (e.g., 2120 in FIG. 26) on a surface of the manufactured mask MK, placing a deposition source DS to face the other surface of the deposition substrate 2120, vaporizing a deposition material contained in the deposition source DS, and letting the vaporized deposition material pass through the mask MK and be deposited on the deposition substrate 2120. Here, the manufacturing of the mask MK may include the method of manufacturing the mask described with reference to FIGS. 13 through 25.

According to a deposition mask, a method of manufacturing the deposition mask, and a method of manufacturing a display device using the deposition mask according to embodiments, it is possible to reduce damage to the mask by increasing the rigidity of the mask and possible to increase the mask manufacturing yield.

However, the effects of the disclosure are not restricted to the one set forth herein. The above and other effects of the disclosure will become more apparent to one of ordinary skill in the art to which the disclosure pertains by referencing the claims.

It will be understood by one of ordinary skill in the art to which the disclosure belongs that the disclosure may be implemented in other specific forms without changing the technical spirit or features of the disclosure. Therefore, it is to be understood that the exemplary embodiments described above are illustrative rather than being restrictive in all aspects. It is to be understood that the scope of the disclosure includes modifications and alterations derived from the disclosure.

What is claimed is:

1. A method of manufacturing a deposition mask, the method comprising:
depositing a first metal layer on a front surface of a first substrate and forming a first opening of the first metal layer and a first bonding portion of the first metal layer by patterning the deposited first metal layer;
forming a cell opening which exposes the first opening from a back surface of the first substrate by etching a portion of the first substrate which corresponds to the first opening from the back surface of the first substrate;
depositing a first inorganic layer on a front surface of a second substrate and forming a base layer by patterning the deposited first inorganic layer;
depositing a second inorganic layer on the front surface of the second substrate comprising the base layer;
depositing a second metal layer on the second inorganic layer and forming a second opening of the second metal layer and a second bonding portion of the second metal layer by patterning the deposited second metal layer;
depositing an insulating layer on the front surface of the second substrate which comprises the second bonding portion and the second inorganic layer and forming a protective layer which covers the second inorganic layer in the second opening by patterning the deposited insulating layer;
forming a plurality of grooves which penetrate the protective layer and the second inorganic layer in the second opening;
placing the front surface of the first substrate and the front surface of the second substrate to face each other and bonding the first bonding portion and the second bonding portion to each other;
removing the second substrate; and
forming a mask membrane which comprises the second inorganic layer disposed in the cell opening by removing the protective layer and the base layer.

2. The method of claim 1, wherein the first substrate comprises silicon (Si).

3. The method of claim 1, wherein the second substrate comprises sapphire.

4. The method of claim 1, wherein the first inorganic layer comprises zinc oxide (ZnO).

5. The method of claim 1, wherein the second inorganic layer comprises gallium nitride (GaN).

6. The method of claim 1, wherein the forming of the plurality of grooves comprises:
forming a photoresist pattern, which comprises the plurality of grooves corresponding to the second opening, on the front surface of the second substrate comprising the second bonding portion and the protective layer; and
etching the protective layer and the second inorganic layer using the photoresist pattern.

7. The method of claim 1, further comprising forming a coating layer which covers an entire surface of the first substrate and an entire surface of the mask membrane using atomic layer deposition.

8. A deposition mask, comprising:
a first substrate comprising a plurality of cell areas and a mask frame area excluding the plurality of cell areas;
a mask membrane disposed in the plurality of cell areas; and
a mask frame disposed in the mask frame area and comprising a bonding portion in which a first metal layer and a second metal layer are bonded to each other,
wherein the mask membrane comprises a second inorganic layer remaining after a second substrate, a first inorganic layer and an insulating layer among the first inorganic layer, the second inorganic layer and the insulating layer sequentially deposited on the second substrate are removed.

9. The deposition mask of claim 8, wherein the first substrate comprises silicon (Si).

10. The deposition mask of claim 8, wherein the second substrate comprises sapphire.

11. The deposition mask of claim 8, wherein the first inorganic layer comprises zinc oxide (ZnO).

12. The deposition mask of claim 8, wherein the second inorganic layer comprises gallium nitride (GaN).

13. The deposition mask of claim 8, further comprising a coating layer covering an entire surface of the first substrate and an entire surface of the mask membrane.

14. A method of manufacturing a display device, the method comprising:
manufacturing a mask;
placing a deposition substrate on a surface of the manufactured mask;
placing a deposition source to face a surface of the deposition substrate; and
vaporizing a deposition material contained in the deposition source and letting the vaporized deposition material pass through the mask and be deposited on the deposition substrate,
wherein the manufacturing of the mask comprises:
depositing a first metal layer on a front surface of a first substrate and forming a first opening of the first metal layer and a first bonding portion of the first metal layer by patterning the deposited first metal layer;
forming a cell opening which exposes the first opening from a back surface of the first substrate by etching a portion of the first substrate which corresponds to the first opening from the back surface of the first substrate;
depositing a first inorganic layer on a front surface of a second substrate and forming a base layer by patterning the deposited first inorganic layer;
depositing a second inorganic layer on the front surface of the second substrate comprising the base layer;
depositing a second metal layer on the second inorganic layer and forming a second opening of the second metal layer and a second bonding portion of the second metal layer by patterning the deposited second metal layer;
depositing an insulating layer on the front surface of the second substrate which comprises the second bonding portion and the second inorganic layer and forming a protective layer which covers the second inorganic layer in the second opening by patterning the deposited insulating layer;
forming a plurality of grooves which penetrate the protective layer and the second inorganic layer in the second opening;
placing the front surface of the first substrate and the front surface of the second substrate to face each other and bonding the first bonding portion and the second bonding portion to each other;
removing the second substrate; and
forming a mask membrane which comprises the second inorganic layer disposed in the cell opening by removing the protective layer and the base layer.

15. The method of claim 14, wherein the first substrate comprises silicon (Si).

16. The method of claim 14, wherein the second substrate comprises sapphire.

17. The method of claim 14, wherein the first inorganic layer comprises zinc oxide (ZnO).

18. The method of claim 14, wherein the second inorganic layer comprises gallium nitride (GaN).

19. The method of claim 14, wherein the forming of the plurality of grooves comprises:
forming a photoresist pattern, which comprises the plurality of grooves corresponding to the second opening, on the front surface of the second substrate comprising the second bonding portion and the protective layer; and
etching the protective layer and the second inorganic layer using the photoresist pattern.

20. The method of claim 14, further comprising forming a coating layer which covers an entire surface of the first substrate and an entire surface of the mask membrane using atomic layer deposition.
